(19) United States
(12) Patent Application Publication
(10) Pub. No.: US 2017/0290208 A1
(43) Pub. Date: Oct. 5, 2017

(54) SHIELDING STRUCTURE OF ELECTRO CONTROL UNIT

(71) Applicant: MANDO CORPORATION, Gyeonggi-do (KR)

(72) Inventor: Young-Jin PARK, Seongnam-si (KR)

(21) Appl. No.: 15/478,115

(22) Filed: Apr. 3, 2017

(30) Foreign Application Priority Data
Apr. 1, 2016 (KR) 10-2016-0039887

(51) Int. Cl. H05K 9/00; H05K 5/03; H05K 5/00

(52) U.S. Cl. CPC H05K 9/0024; H05K 5/0017; H05K 5/03

(57) ABSTRACT

Disclosed herein is an electronic control unit (ECU). The ECU according to one aspect of the present disclosure includes a housing in which a printed circuit board (PCB), on which electronic devices configured to control electrically operated components are mounted, is installed, and a cover installed to block one side of the housing, wherein a slot having both ends disconnected to each other is formed around one electronic device among the electronic devices mounted on the PCB, and a part of a shield member is provided to pass through the slot and to surround the electronic device.

### CROSS-REFERENCE TO RELATED APPLICATION

This application claims the benefit of Korean Patent Application No. 2010-0128027, filed on Dec. 15, 2010 in the Korean Intellectual Property Office, the disclosure of which is incorporated herein by reference.

### BACKGROUND

### 1. Field

Embodiments of the present disclosure relate to an electronic control unit (ECU), and more particularly, to a shield structure of an electronic device provided in an ECU.

### 2. Description of the Related Art

Recently, since various additional functions have been applied to pursue safety and comfort of vehicles, electronic equipment for electronically controlling mechanical devices such as a braking device and a suspension device used in the vehicles is acceleratedly progressed, and thus, the importance of an electronic control unit (ECU) in the vehicles is gradually increasing.

Particularly, a precise motor control of an ECU used for an integrated dynamic brake (IDB) system configured to detect a displacement according to a brake pedal force, drive a motor, and generate a braking hydraulic pressure or an electronic parking system (EPS) configured to drive a motor and operate a brake cable has become an important factor.

Such an ECU includes a printed circuit board (PCB), on which various electronic devices for controlling electrically operated components are mounted, and a housing and cover provided to protect the PCB. That is, a hydraulic block on which a plurality of solenoid valves configured to control a braking hydraulic pressure and the like are mounted and a motor configured to generate a braking hydraulic pressure or operate a parking cable according to a displacement of a brake pedal are installed in the ECU. Here, one of the electronic devices is provided as a motor position sensor (MPS) for detecting a rotation of the motor to control the motor and mounted on the PCB. More specifically, the MPS is provided to be spaced a predetermined distance from a lower end portion of the motor installed in the ECU, that is, a magnet unit installed at an end of a rotation shaft thereof. Accordingly, the MPS detects a magnetic flux signal of the magnet unit installed at the rotation shaft and then recognizes the rotation of the motor.

Here, a space between the MPS and the magnet installed at the rotation shaft is provided to be open. As a result, there is a problem in that the electronic devices installed on the PCB malfunction due to a magnetic field generated by the magnet installed at the rotation shaft when the rotation shaft rotates.

### SUMMARY

Therefore, it is an aspect of the present disclosure to provide an electronic control unit (ECU) capable of preventing electronic devices mounted on a printed circuit board (PCB) from being influenced by a magnetic field of a magnet and easily detecting a magnetic flux signal of a motor by combining a shield member and the ECU.

Additional aspects of the disclosure will be set forth in part in the description which follows and, in part, will be obvious from the description, or may be learned by practice of the disclosure.

In accordance with one aspect of the present disclosure, an electronic control unit (ECU) includes a housing in which a printed circuit board (PCB), on which electronic devices configured to control electrically operated components are mounted, is installed, and a cover installed to block one side of the housing, wherein a slot having both ends disconnected to each other is formed around one electronic device among the electronic devices mounted on the PCB, and a part of a shield member is provided to pass through the slot and surround the electronic device.

The electronic device may be provided as a motor position sensor (MPS) configured to control a motor, and the MPS may be provided to face a magnet unit installed at an end of a rotation shaft of the motor.

The shield member may be formed to surround the electronic device together with the magnet unit.

A plurality of slots identical to the slot may be formed, and the shield member may have a shape corresponding to the slot and may be formed in a cylindrical shape having a hollow center.

A cut section may be formed in the shield member so that the PCB excluding a portion in which the slot is formed and provided between both ends of the slot is inserted into the cut section.

The shield member may be formed integrally with the cover.

A cut section having a predetermined length may be formed in one side of the shield member so that the PCB provided between both ends of the slot is inserted into the cut section, and the other side of the shield member may be coupled to the cover.

A coupling groove corresponding to the shield member may be formed in the cover so that the other side of the shield member is inserted into and coupled to the coupling groove.

### BRIEF DESCRIPTION OF THE DRAWINGS

Although the present disclosure will be specifically described with reference to the accompanying drawings, since such drawings illustrate exemplary embodiments, technical ideas of the present disclosure should not be limited thereto.

These and/or other aspects of the disclosure will become apparent and more readily appreciated from the following description of the embodiments, taken in conjunction with the accompanying drawings of which:

FIG. 1 is an exploded perspective view illustrating a state in which an electronic control unit (ECU) according to one embodiment of the present disclosure is being coupled to a motor;

FIG. 2 is a partial perspective view illustrating a state in which a shield member is being coupled to a printed circuit board (PCB) of the ECU according to one embodiment of the present disclosure;

FIG. 3 is a coupled perspective view of FIG. 2;

FIG. 4 is a cross-sectional view illustrating a state in which a magnetic field of a magnet installed at a rotation shaft of the motor is shielded by the shield member of the ECU according to one embodiment of the present disclosure;

FIG. 5 is a view illustrating a state in which a shield member is being coupled to a PCB of an ECU according to another embodiment of the present disclosure; and

FIG. 6 is a view illustrating a state in which a shield member of an ECU according to still another embodiment of the present disclosure is being coupled to a cover.

### DETAILED DESCRIPTION

Hereinafter, embodiments of the present disclosure will be described in detail with reference to the accompanying drawings. The present embodiments are provided in order to fully explain the spirit and scope of the present disclosure to those skilled in the art. Thus, the present disclosure is not to be construed as limited to the present embodiments set forth herein and may be embodied in other various forms. Parts irrelevant to the description are omitted in the drawings in order to clearly explain the present disclosure. Sizes of elements in the drawings may be exaggerated in order to facilitate understanding.

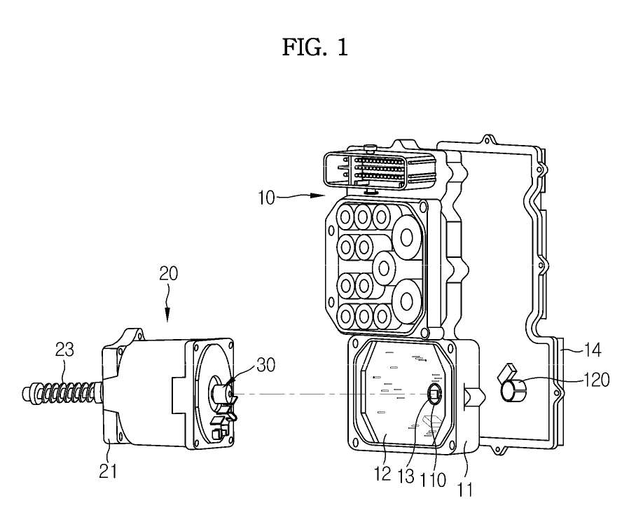

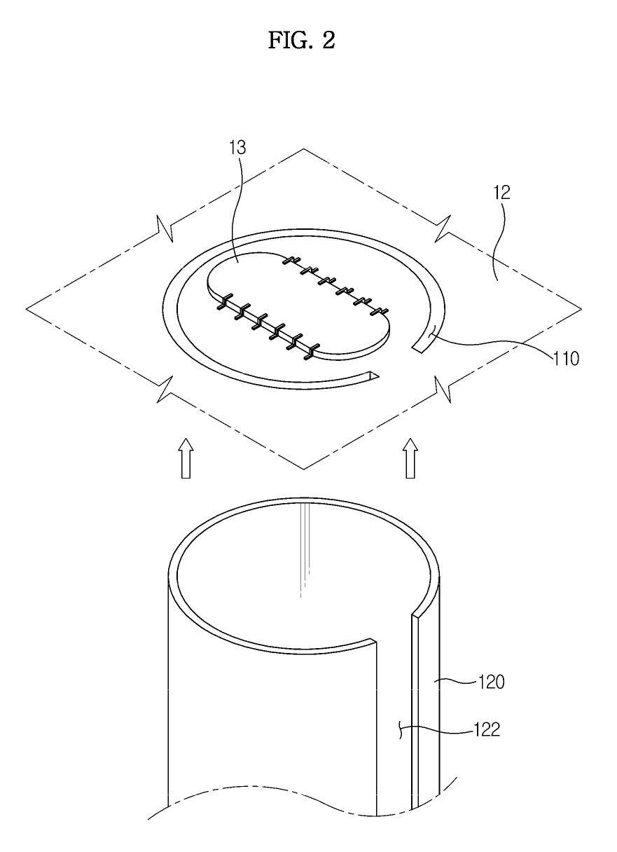

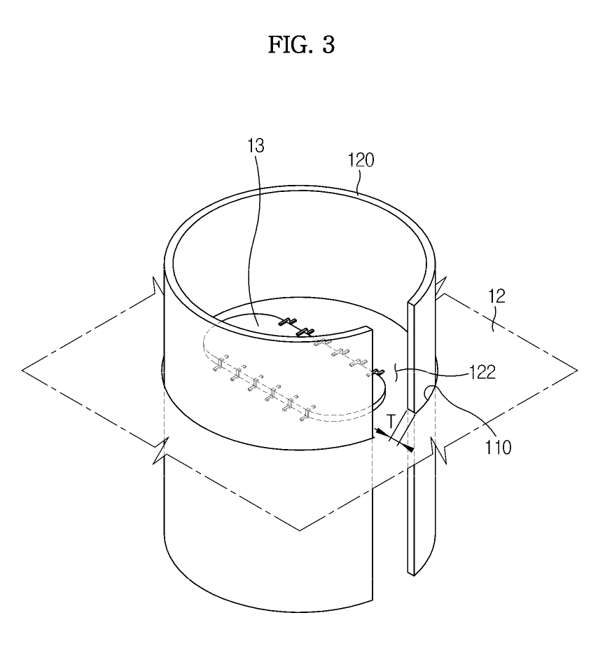

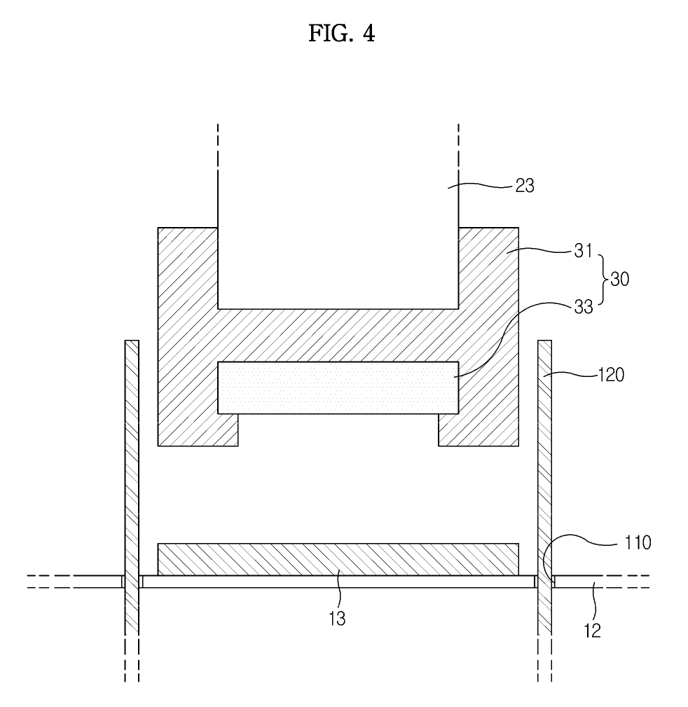

FIG. 1 is an exploded perspective view illustrating a state in which an electronic control unit (ECU) according to one embodiment of the present disclosure is being coupled to a motor, FIG. 2 is a partial perspective view illustrating a state in which a shield member is being coupled to a printed circuit board (PCB) of the ECU according to one embodiment of the present disclosure, FIG. 3 is a coupled perspective view of FIG. 2, and FIG. 4 is a cross-sectional view illustrating a state in which a magnetic field of a magnet installed at a rotation shaft of the motor is shielded by the shield member of the ECU according to one embodiment of the present disclosure.

Referring to FIGS. 1 to 4, an electronic control unit (ECU) 10 includes a housing 11 having one open side, a printed circuit board (PCB) 12 which is accommodated in and fixed to the housing 11 and on which various electronic devices are mounted, a cover 14 installed to block the one open side of the housing 11, and a shield member 120.

The other side of the housing 11 is partitioned into a hydraulic block (not shown) in which a plurality of solenoid valves and the like configured to adjust a braking hydraulic pressure are provided and a portion at which a motor 20 is installed and provided in an open state. In addition, one electronic device among various electronic devices mounted on the PCB 12 is provided as a motor position sensor (MPS) 13 configured to detect a magnetic flux signal of the motor 20, and the MPS 13 is mounted on a portion at which the motor 20 is installed. That is, the MPS 13 is mounted on a portion corresponding to a magnet unit 30 installed at a rotation shaft 23 of the motor 20, which will be described below, when the motor 20 is installed in the housing 11.

Meanwhile, according to one aspect of the present disclosure, although the ECU 10 is illustrated as a type in which the ECU 10 is combined with a hydraulic block (not shown) to control a braking hydraulic pressure, the ECU 10 is not limited thereto, and there is a only difference in shape according to a usage of the ECU 10. It should be understood that any structure, in which the motor 20 is installed in the housing 11 in which the MPS 13 is mounted on the PCB 12, may be employed.

The motor 20 includes a motor housing 21 coupled to a predetermined portion of the other side of the housing 11, a rotor (not shown) having the rotation shaft 23, which passes through the motor housing 21, installed at the center thereof, a stator (not shown) configured to generate a rotational driving force for the rotor, and the magnet unit 30 installed at an end of the rotation shaft 23. Here, the magnet unit 30 includes a holder 31 installed at the end of the rotation shaft 23 and a magnet 33 fixed by the holder 31.

Such a motor 20 is installed in the housing 11 of the ECU 10 by a bolt (not shown) and the like such that the magnet unit 30 faces the PCB 12. That is, when the motor 20 and the ECU 10 are coupled, the MPS 13 is provided at a position corresponding to the magnet 33 provided at the end of the rotation shaft 23 of the motor 20 to detect a magnetic flux signal of the motor 20. Here, when the motor 20 operates, the shield member 120 is provided to shield a magnetic field generated by the magnet 33 and prevents electronic devices mounted on the PCB 12 from being influenced by the magnetic field.

The shield member 120 is formed to pass through a slot 110 formed in the PCB 12 on which the MPS 13 is mounted and surrounds the MPS 13.

Here, the slot 110 is formed to have a predetermined length around the MPS 13 without both ends being connected to each other. This is to maintain a state in which the MPS 13, which was mounted on the PCB 12, is mounted on the PCB 12. As illustrated in the drawings, the slot 110 is formed in an approximately ‘C-character’ shape as a single shape. Here, it is preferable for both ends of the slot 110 to be spaced a predetermined distance from each other at adjacent positions and face each other. This is to minimize a magnetic field exposed to the outside using the shield member 120 which passes through the slot 110.

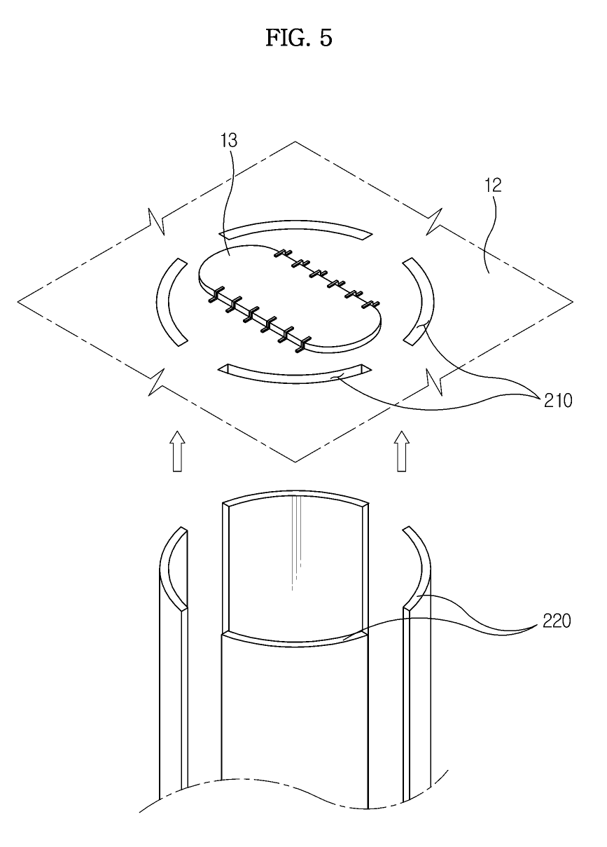

Meanwhile, although the slot 110 is illustrated as being provided as a single form, the slot 110 is not limited thereto, and may also be provided as a plurality of slots. For example, a state in which a shield member is being coupled to a PCB of an ECU according to another embodiment of the present disclosure is illustrated in FIG. 5. As illustrated in FIG. 5, four slots 210 may be formed around an MPS 13 on a PCB 12. Here, a plurality of slots 210 are formed to be spaced a predetermined distance from ends of adjacent slots 210 and face each other.

In addition, although an extended shape of the slot 110 or 210 is illustrated in an approximately circular shape, the extended shape is not limited thereto, and may be formed in a polygonal shape such as a tetragonal or a triangular shape. Accordingly, as long as the shield member 120 or 220 which will be described below has a shape respectively corresponding to the slot 110 or 210 and passes through the slot 110 or 210 to surround the MPS 13 together with the magnet unit 30, the shield member 120 or 220 may be formed in any shape. Meanwhile, since the shield member 220 illustrated in FIG. 5 performs the same function as the shield member 120 of the previous embodiment, the shield member 220 may be sufficiently understood through a description of the shield member 120 which will be described below, and thus a detail description of the shield member 220 herein will be omitted.

Referring again to FIGS. 1 to 4, the shield member 120 is formed such that one part of the shield member 120 passes through the slot 110 and surrounds the MPS 13. More specifically, the shield member 120 has a shape corresponding to the slot 110. In addition, the shield member 120 may be provided to have a predetermined length and a cylindrical shape having a hollow center. That is, since the shield member 120 is provided in a shape corresponding to the slot 110, a cut section 122 is formed in the shield member 120 so that the PCB 12 excluding a portion in which the slot 110 is formed and provided between both ends of the slot 110 is inserted into the cut section 122.

Such a shield member 120 may be provided integrally with the cover 14 or may be provided separately from and coupled to the cover 14. For example, as illustrated in FIG. 1, the shield member 120 may be formed integrally with the cover 14 by injection molding. Accordingly, when the cover 14 is installed at one side of the housing 11, the shield member 120 and the slot 110 have to be provided at corresponding positions so that the shield member 120 passes through the slot 110.

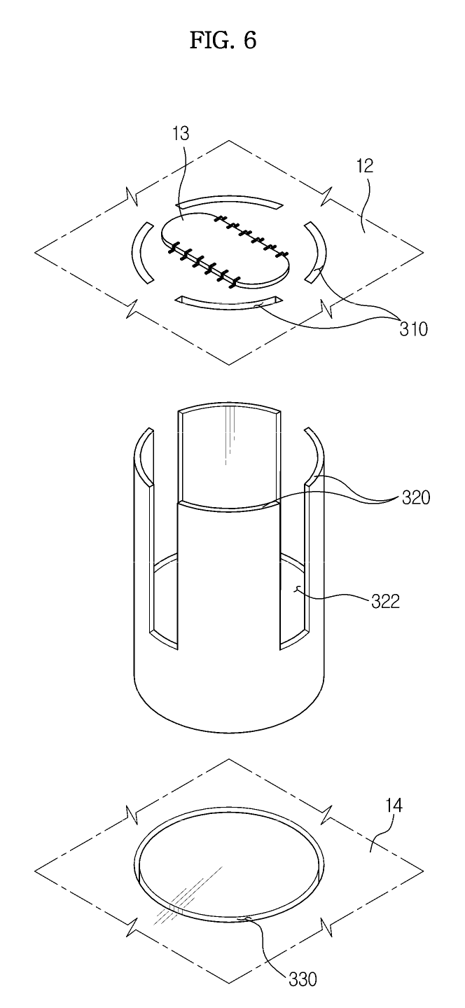

In addition, a state in which a shield member of an ECU according to still another embodiment of the present disclosure is being coupled to a cover is illustrated in FIG. 6. That is, when a shield member 320 is provided separately from and coupled to a cover 14, a coupling groove 330 is formed in the cover 14 so that the shield member 320 is inserted into and coupled to the coupling groove 330. The coupling groove 330 is formed in a shape corresponding to the shield member 320, and thus the shield member 320 may be forcibly inserted into and coupled to the coupling groove 330. In addition, a cut section 322 having a predetermined length is formed in one side of the shield member 320 so that a PCB 12 provided between both ends of a slot 310 is inserted into the cut section 322, and the other side is coupled to the cover 14. The shield member 320 is formed in a single body connected through the other side so that the shield member 320 is not separated by the cut section 322 formed in the one side.

Referring again to FIGS. 1 to 4, it is preferable for the shield member 120 to have a thickness T which is less than a width of the slot 110 to easily pass through the slot 110.

When the shield member 120 is installed by passing through the slot 110, the shield member 120 is disposed to surround the MPS 13 together with the magnet unit 30 provided to face the MPS 13. That is, as illustrated in FIG. 4, since the shield member 120 which passed through the slot 110 is disposed to surround an outer circumferential surface in a state in which the shield member 120 is spaced a predetermined distance from the magnet unit 30, a magnetic field generated by the magnet 33 is shielded.

As a result, since the ECU 10 according to the embodiment of the present disclosure prevents peripheral components from being influenced by a magnetic field of the magnet through a simple assembly structure by providing integrally with or installing separately from the shield member 120 on the cover 14, the reliability of a product can be improved, and ease of manufacture and assembly can be secured.

As is apparent from the above description, since an ECU according to one embodiment of the present disclosure includes a shield member configured to prevent surrounding components from being influenced by a magnetic field of a magnet installed in a motor, the ECU can prevent a problem that a system malfunctions due to an influence of the magnetic field.

In addition, since a slot is formed in a PCB and a shield member is inserted into and coupled to the slot, an ECU is easy to manufacture and assemble.

In addition, since a shield member surrounds an MPS and a magnet installed at a rotation shaft of a motor facing each other, an ECU is not influenced by an electric signal from the outside, and thus, can easily detect a magnetic flux signal of the motor.

Although a few embodiments of the present disclosure have been shown and described, it would be appreciated by those skilled in the art that changes may be made in these embodiments without departing from the principles and spirit of the disclosure, the scope of which is defined in the claims and their equivalents

[Reference Numerals]

| | |
|---|---|
| 10: ELECTRONIC CONTROL | 11: HOUSING |
| UNIT | |
| 12: PRINTED CIRCUIT BOARD | 13: MOTOR POSITION SENSOR |
| 14: COVER | 20: MOTOR |
| 23: ROTATION SHAFT | 30: MAGNET UNIT |
| 110, 210, and 310: SLOT | 120, 220, and 320: SHIELD |
| | MEMBER |

What is claimed is:

1. An electronic control unit comprising:
a housing in which a printed circuit board, on which electronic devices configured to control electrically operated components are mounted, is installed; and
a cover installed to block one side of the housing,
wherein:
a slot having both ends disconnected to each other is formed around one electronic device among the electronic devices mounted on the printed circuit board; and
a part of a shield member is provided to pass through the slot and to surround the electronic device.

2. The electronic control unit of claim 1, wherein:
the electronic device is provided as a motor position sensor configured to control a motor; and
the motor position sensor is provided to face a magnet unit installed at an end of a rotation shaft of the motor.

3. The electronic control unit of claim 2, wherein the shield member is formed to surround the electronic device together with the magnet unit.

4. The electronic control unit of claim 1, wherein:
a plurality of slots identical to the slot are formed; and
the shield member has a shape corresponding to the slot and is formed in a cylindrical shape having a hollow center.

5. The electronic control unit of claim 1, wherein a cut section is formed in the shield member so that the printed circuit board excluding a portion in which the slot is formed and provided between both ends of the slot is inserted into the cut section.

6. The electronic control unit of claim 1, wherein the shield member is formed integrally with the cover.

7. The electronic control unit of claim 1, wherein:
a cut section having a predetermined length is formed in one side of the shield member so that the printed circuit board provided between both ends of the slot is inserted into the cut section; and
the other side of the shield member is coupled to the cover.

8. The electronic control unit of claim 7, wherein a coupling groove corresponding to the shield member is formed in the cover so that the other side of the shield member is inserted into and coupled to the coupling groove.
